(19) United States
(12) Patent Application Publication
(10) Pub. No.: US 2008/0087548 A1
(43) Pub. Date: Apr. 17, 2008

(54) Mandrels for Electroforming Printing Screens, and Electroforming Apparatus

(76) Inventor: Lee Edward James Bailey, Weymouth (GB)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 11/577,687

(22) PCT Filed: Oct. 19, 2005
(86) PCT No.: PCT/GB05/04016

§ 371 Date: Apr. 20, 2007

(30) Foreign Application Priority Data
Oct. 20, 2004 (GB) 0423263.3

(51) Int. Cl. B41N 1/04; B41C 1/14; G03F 7/12; B41F 15/34

(52) U.S. Cl. 205/69; 118/406

(57) ABSTRACT

A mandrel for electroforming printing screens, the mandrel comprising: a mandrel plate onto which metal is to be deposited to form a printing screen, the mandrel plate including a main deposition surface onto which metal is to be deposited to define a main body of the printing screen, at least one pair of edge sections at opposed edges of the main deposition surface which include edge deposition surfaces which extend out of a plane defined by the main deposition surface onto which metal is to be deposited to define attachment elements of the printing screen, and corner sections at respective corners of the deposition surface; non-conductive elements, as edge elements, which are disposed at the edge sections such as to define an extent of the edge sections; and non-conductive elements, as corner elements, which are disposed at the corner sections such as to shield the same and define an extent of the main deposition surface at the corner sections.

The present invention relates to a mandrel for electroforming printing screens, an electroforming system for electroforming printing screens, a method of electroforming printing screens, and an electroformed printing screen which incorporates attachment elements at the edges thereof for mechanical engagement with a mounting frame.

Printing screens, which are often alternatively referred to as printing stencils, are used in the manufacture of circuit boards in printing a medium, typically either a solder paste or an adhesive, onto a circuit board.

Electroforming has been commonly used to fabricate flat printing screens, with such printing screens being disclosed, for example, in U.S. Pat. No. 5,359,928 and U.S. Pat. No. 5,478,699.

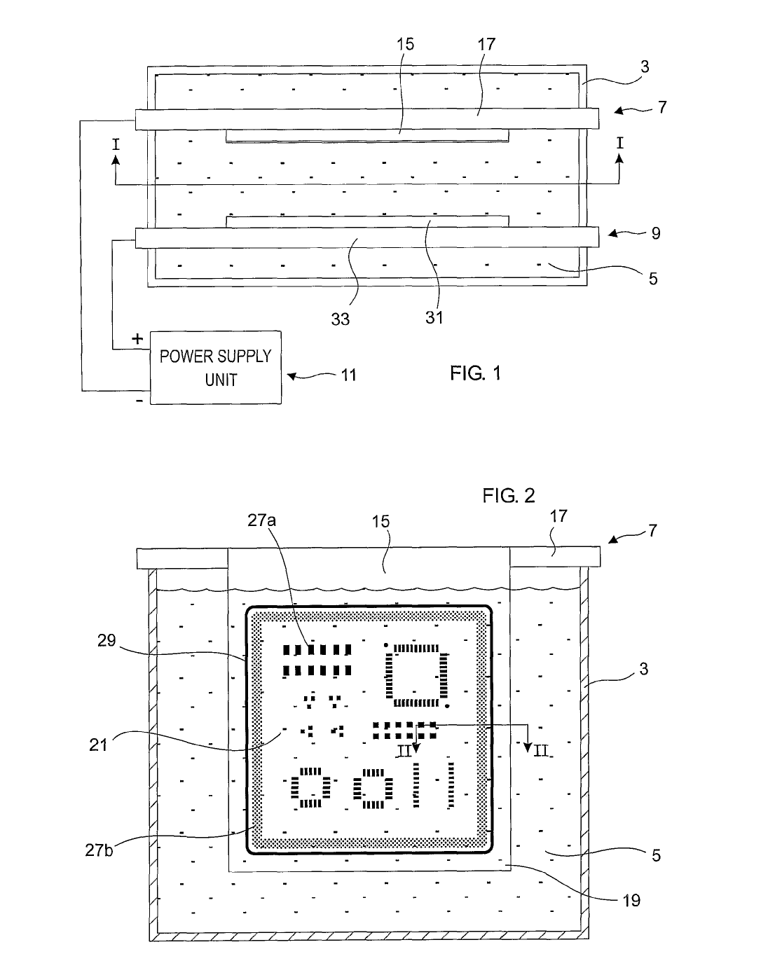

The electroforming of such printing screens will now be described with reference to FIGS. 1 to 6.

The electroforming system comprises a bath 3 which contains an electrolyte solution 5, a mandrel unit 7 which is disposed in the bath 3 and onto which metal is electrodeposited to form a printing screen, an anode unit 9 which is disposed in the bath 3 such as to provide a source of ions of the metal to be deposited, and a power supply unit 11 which is electrically connected to the mandrel unit 7 and the anode unit 9 and operable to drive an electric current through the electrolyte solution 5, with the negative supply of the power supply unit 11 being connected to the mandrel unit 7 and the positive supply of the power supply unit 11 being connected to the anode unit 9.

The electrolyte solution 5 is typically an aqueous solution which contains a dissolved salt of the metal to be deposited, commonly nickel, and levellers which provide for control of the hardness of the deposited metal.

The mandrel unit 7 comprises a mandrel 15 onto which a printing screen is to be electroformed, and a supporting member 17, typically a supporting bar, for supporting the mandrel 15 in the bath 3 and providing an electrical connection therewith.

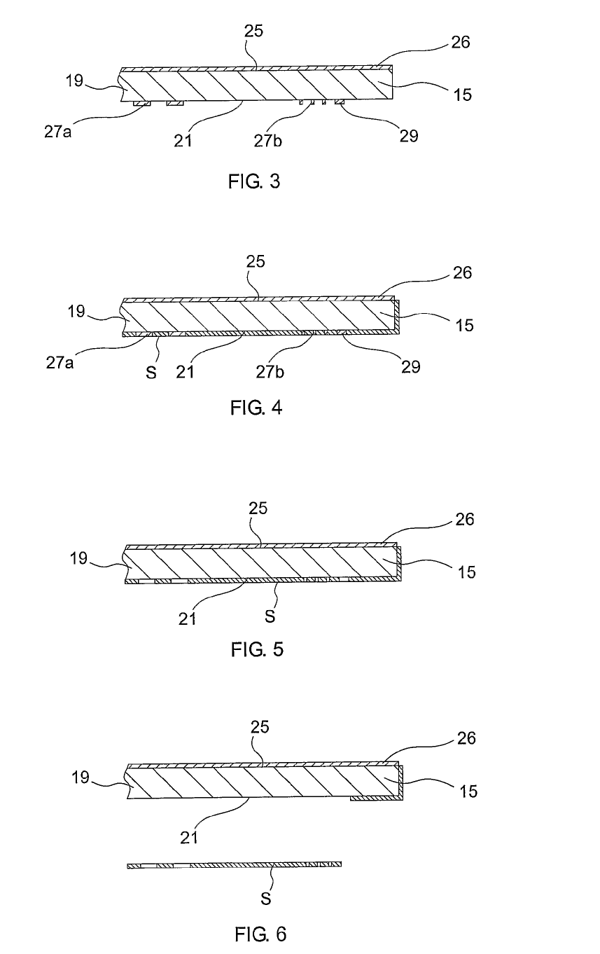

FIG. 3 illustrates a fragmentary sectional view through the mandrel 15.

The mandrel 15 comprises a flat metal plate 19, typically rectangular in shape, which includes first and second oppositely-directed flat, major surfaces 21, 25, where one major surface 21 is a deposition surface onto which metal is deposited to form a printing screen, as will be described in more detail hereinbelow.

The mandrel 15 further comprises a plurality of non-conductive aperture-defining elements 27a, 27b, formed of resist, which shield regions on the deposition surface 21 onto which metal is not to be deposited, with these elements 27a, 27b corresponding to the apertures to be formed in the printing screen, both as printing apertures through which a pattern of a printing medium is to be printed and attachment apertures which key to a bonding glue in attachment to a mounting frame, and a non-conductive bounding element 29, formed of resist, which bounds a region of the deposition surface 21 and defines the extent of the printing screen to be formed.

The mandrel 15 further comprises a non-conductive surface-covering element 26, formed of resist, on the other major surface 25 which acts to prevent the deposition of metal thereon.

The anode unit 9 comprises an anode plate 31, typically of the same rectangular shape as the mandrel 15, which is formed of the metal to be deposited as the printing screen, and a supporting member 33, typically a supporting bar, for supporting the anode plate 31 in the bath 3 and providing an electrical connection therewith.

In a preferred arrangement the deposition surface 21 of the mandrel 15 and the anode plate 31 are disposed in opposed, parallel relation at a predetermined spacing.

In operation, the power supply unit 11 is actuated to drive an electric current through the electrolyte solution 5 between the mandrel unit 7 and the anode unit 9. This current causes metal ions to migrate from the anode plate 31 to the exposed regions of the deposition surface 21 of the mandrel plate 19, at which exposed regions the metal ions deposit as the metal, building up the printing screen by the continued deposition of metal on the deposition surface 21 of the mandrel plate 19.

This process is allowed to continue until a layer of the required thickness, which constitutes a printing screen S, has been built up on the deposition surface 21 of the mandrel plate 19, as illustrated in FIG. 4, at which point the power supply unit 11 is de-actuated and the mandrel unit 7 removed from the bath 3.

The non-conductive elements 27a, 27b, 29 on the deposition surface 21 of the mandrel plate 19 are then removed, by stripping the resist, leaving the printing screen S, as illustrated in FIG. 5.

The printing screen S is then separated from the mandrel 15, as illustrated in FIG. 6, by lifting at the edges revealed by removal of the bounding element 29, and, following cleaning, is ready for use.

Electroforming has also been used to fabricate a printing screen which incorporates upstanding attachment elements which encompass the periphery of the main body of the printing screen and provide for fixing of the printing screen over a mounting frame which maintains the printing screen at a predetermined tension, with the electroforming of such a printing screen being disclosed in EP-A-0029348.

Whilst electroforming is increasingly being used to fabricate printing screens, the existing electroformed printing screens do not allow for mounting in a mounting frame and the repeated, active tensioning of the printing screen between tensioned and untensioned states while mounted in the mounting frame.

It is thus an aim of the present invention to provide a mandrel for electroforming printing screens, an electroforming system for electroforming printing screens, a method of electroforming printing screens, and an electroformed printing screen which incorporates attachment elements at the edges thereof which allow for repeated, active tensioning of the printing screen between tensioned and untensioned states while mounted in a mounting frame.

In one aspect the present invention provides a mandrel for electroforming printing screens, the mandrel comprising: a mandrel plate onto which metal is to be deposited to form a printing screen, the mandrel plate including a main deposition surface onto which metal is to be deposited to define a main body of the printing screen, at least one pair of edge sections at opposed edges of the main deposition surface which include edge deposition surfaces which extend out of a plane defined by the main deposition surface onto which metal is to be deposited to define attachment elements of the printing screen, and corner sections at respective corners of the deposition surface; non-conductive elements, as edge elements, which are disposed at the edge sections such as to define an extent of the edge sections; and non-conductive elements, as corner elements, which are disposed at the corner sections such as to shield the same and define an extent of the main deposition surface at the corner sections.

In one embodiment the mandrel further comprises: non-conductive elements disposed on the main deposition surface which shield regions of the main deposition surface, corresponding to printing apertures, onto which metal is not to be deposited.

In one embodiment each edge deposition surface includes a surface section which extends laterally relative to the main deposition surface.

In one embodiment the surface section extends laterally outwardly relative to the respective edge of the main deposition surface, which provides for deposition of an outwardly-projecting part.

In another embodiment the surface section extends laterally inwardly relative to the respective edge of the main deposition surface, which provides for deposition of an inwardly-projecting part.

Preferably, the surface section returns inwardly a distance of about 0.5 mm.

In one embodiment the surface section comprises a substantially straight section.

In another embodiment the surface section comprises an arcuate section.

In one embodiment the surface section extends rearwardly of the main deposition surface.

In another embodiment each edge deposition surface includes first and second surface sections, wherein the first surface section extends substantially orthogonally relative to the main deposition surface and the second surface section extends laterally relative to the main deposition surface.

In one embodiment the second surface section extends laterally outwardly relative to the respective edge of the main deposition surface, which provides for deposition of an outwardly-projecting part.

In another embodiment the second surface section extends laterally inwardly relative to the respective edge of the main deposition surface, which provides for deposition of an inwardly-projecting part.

Preferably, the second surface section returns inwardly a distance of about 0.5 mm.

In one embodiment the second surface section comprises a substantially straight section.

In another embodiment the second surface section comprises an arcuate section.

In one embodiment the first surface section extends from the respective edge of the main deposition surface and the second surface section extends from the first surface section.

In another embodiment the second surface section extends from the respective edge of the main deposition surface and the first surface section extends from the second surface section.

In one embodiment the first and second surface sections extend rearwardly of the main deposition surface.

In a further embodiment each edge deposition surface includes first and second surface sections, wherein the first surface section extends laterally in one sense relative to the main deposition surface and the second surface section extends laterally in the other sense relative to the main deposition surface.

In one embodiment the first surface section extends laterally outwardly relative to the respective edge of the main deposition surface, which provides for deposition of an outwardly-projecting part, and the second surface section extends laterally inwardly relative to the respective edge of the main deposition surface, which provides for deposition of an inwardly-projecting part.

Preferably, the second surface section returns inwardly a distance of about 0.5 mm.

In one embodiment one or both of the first and second surface sections comprise a substantially straight section.

In one embodiment one or both of the first and second surface sections comprise an arcuate section.

In one embodiment the first and second surface sections extend rearwardly of the main deposition surface.

In a yet further embodiment the edge sections each comprise a channel at the respective edge of the main deposition surface in which metal is deposited to form an attachment element.

Preferably, the channel has a width of about 0.5 mm to about 0.6 mm.

Preferably, the channel has a width of about 0.5 mm or about 0.6 mm.

In one embodiment the channel has a substantially U-shaped section.

In one embodiment the mandrel plate includes first and second pairs of edge sections at opposed edges of the main deposition surface.

Preferably, the edge sections and the corner sections define a continuous peripheral section.

The present invention also extends to an electroforming system including the above-described mandrel.

The present invention further extends to a method of electroforming printing screens, comprising the steps of: providing the above-described mandrel in an electroforming bath; and electrodepositing metal on the mandrel plate such as to form a printing screen.

In another aspect the present invention provides an electroformed printing screen, comprising a main body including a pattern of printing apertures through which a printing medium is in use printed, and at least one pair of attachment elements at opposed edges of the main body, wherein the attachment elements each extend out of a plane defined by the main body and along only part of a length of the respective edge of the main body.

In one embodiment each corner of the main body is recessed or cut away, such that the attachment elements are separate from one another.

In one embodiment each attachment element includes a projecting part which extends laterally relative to the respective edge of the main body.

In one embodiment the projecting part extends laterally outwardly relative to the respective edge of the main body.

In another embodiment the projecting part extends laterally inwardly relative to the respective edge of the main body.

Preferably, the projecting part returns inwardly a distance of about 0.5 mm.

In one embodiment the projecting part comprises a substantially straight section.

In another embodiment the projecting part comprises an arcuate section.

In one embodiment the projecting part extends rearwardly of the main body.

In another embodiment each attachment element includes first and second projecting parts, wherein the first projecting part extends substantially orthogonally relative to the main body and the second projecting part extends laterally relative to the main body.

In one embodiment the second projecting part extends laterally outwardly relative to the respective edge of the main body.

In another embodiment the second projecting part extends laterally inwardly relative to the respective edge of the main body.

Preferably, the second projecting part returns inwardly a distance of about 0.5 mm.

In one embodiment the second projecting part comprises a substantially straight section.

In another embodiment the second projecting part comprises an arcuate section.

In one embodiment the first projecting part extends from the respective edge of the main body and the second projecting part extends from the first projecting part.

In another embodiment the second projecting part extends from the respective edge of the main body and the first projecting part extends from the second projecting part.

In one embodiment the first and second projecting parts extend rearwardly of the main body.

In a further embodiment each attachment element includes first and second projecting parts, wherein the first projecting part extends laterally in one sense relative to the main body and the second projecting part extends laterally in the other sense relative to the main body.

In one embodiment the first projecting part extends laterally outwardly relative to the respective edge of the main body, and the second projecting part extends laterally inwardly relative to the respective edge of the main body.

Preferably, the second projecting part returns inwardly a distance of about 0.5 mm.

In one embodiment one or both of the first and second projecting parts comprise a substantially straight section.

In another embodiment one or both of the first and second projecting parts comprise an arcuate section.

In one embodiment the first and second projecting parts extend rearwardly of the main body.

In a yet further embodiment the attachment elements each comprise an open section.

Preferably, the open section has a width of about 0.5 mm to about 0.6 mm.

Preferably, the open section has a width of about 0.5 mm or about 0.6 mm.

In one embodiment the open section comprises a substantially U-shaped section.

In a still further embodiment the attachment elements each comprise a bead.

Preferably, the bead has a width of about 0.5 mm to about 0.6 mm.

Preferably, the bead has a width of about 0.5 mm or about 0.6 mm.

In one embodiment the bead comprises a hollow body.

In one embodiment the printing screen comprises first and second pairs of opposed attachment elements.

In a further aspect the present invention provides a mandrel for electroforming printing screens, the mandrel comprising: a mandrel plate onto which metal is to be deposited to form a printing screen, the mandrel plate including a deposition surface onto which metal is to be deposited to define a main body of the printing screen, and at least one pair of edge sections at opposed edges of the deposition surface which include surfaces which extend out of a plane defined by the deposition surface onto which metal is to be deposited to define attachment elements of the printing screen; and non-conductive elements disposed at the edge sections such as to define an extent of the edge sections.

In a yet further aspect the present invention provides an electroformed printing screen, comprising a main body including a pattern of printing apertures through which a printing medium is in use printed, and at least one pair of attachment elements at opposed edges of the main body, wherein the attachment elements extend out of a plane defined by the main body.

Preferred embodiments of the present invention will now be described hereinbelow by way of example only with reference to the accompanying drawings, in which:

FIG. 1 illustrates a representative prior art electroforming system;

FIG. 2 illustrates a vertical sectional view (along section I-I in FIG. 1) through the electroforming bath of the electroforming system of FIG. 1;

FIG. 3 illustrates a sectional view (along section II-II in FIG. 2) of the mandrel of the electroforming system of FIG. 1;

FIG. 4 illustrates a sectional view (along section II-II in FIG. 2) of the mandrel of the electroforming system of FIG. 1, where including a printing screen electroformed thereon;

FIG. 5 illustrates a sectional view (along section II-II in FIG. 2) of the mandrel of the electroforming system of FIG. 1, where the aperture-defining and bounding elements are removed from the deposition surface of the mandrel following formation of the printing screen;

FIG. 6 illustrates a sectional view (along section II-II in FIG. 2) of the mandrel of the electroforming system of FIG. 1, where the electroformed printing screen is removed from the deposition surface of the mandrel;

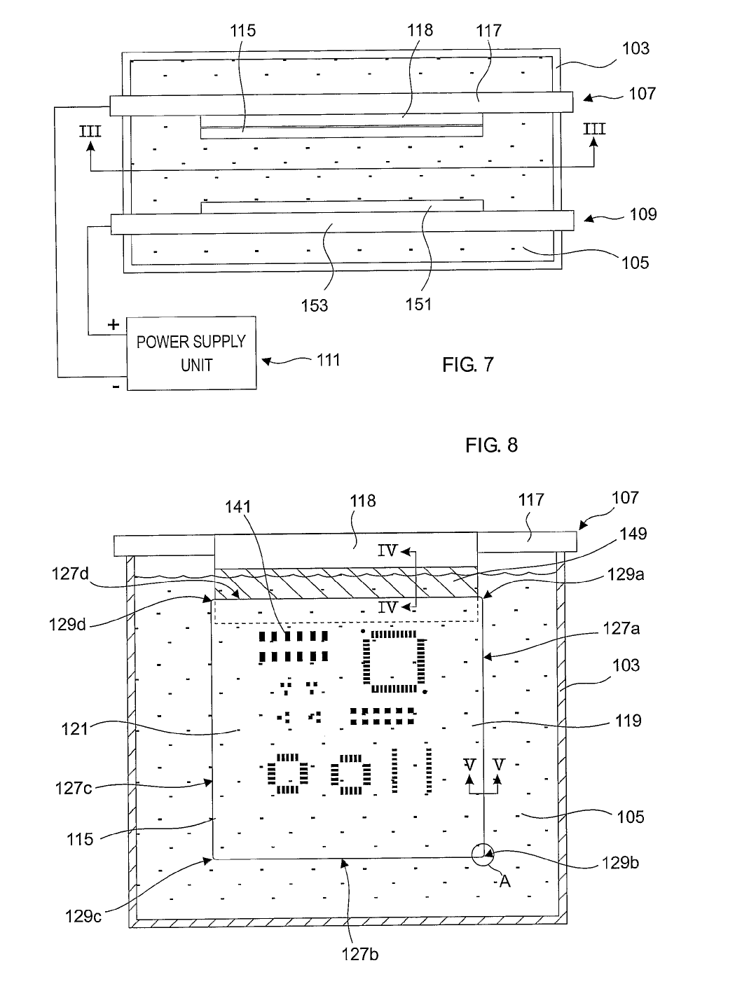

FIG. 7 illustrates an electroforming system in accordance with a first embodiment of the present invention;

FIG. 8 illustrates a vertical sectional view (along section III-III in FIG. 7) through the electroforming bath of the electroforming system of FIG. 7;

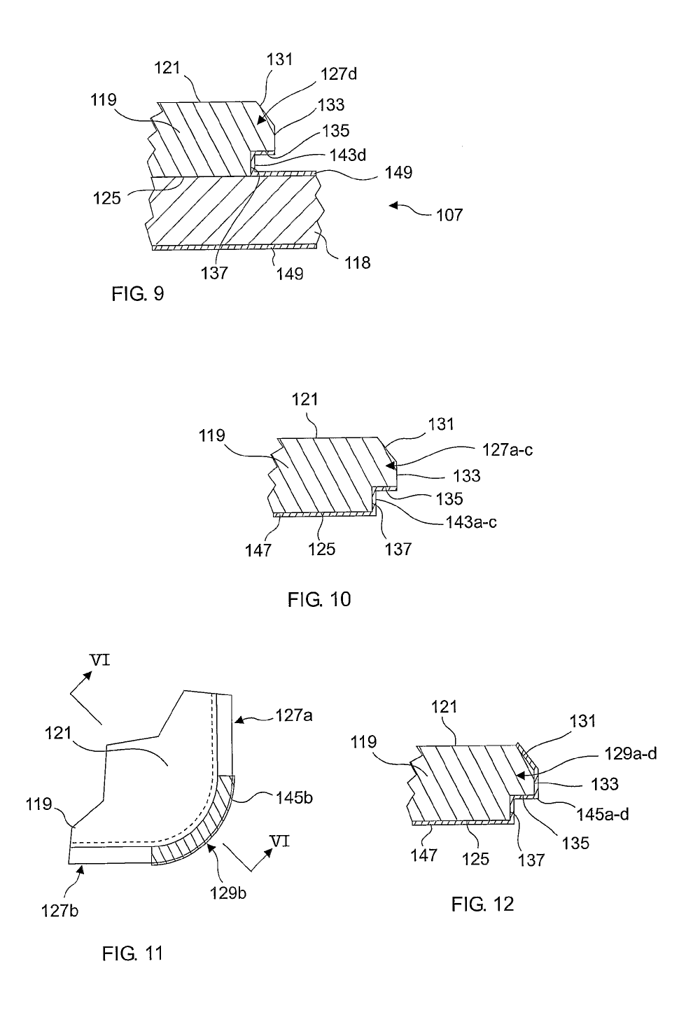

FIG. 9 illustrates a sectional view (along section IV-IV in FIG. 8) of one edge section of the mandrel of the electroforming system of FIG. 7;

FIG. 10 illustrates a sectional view (along section V-V in FIG. 8) of one of the other edge sections of the mandrel of the electroforming system of FIG. 7;

FIG. 11 illustrates a plan view (region A in FIG. 8) of one of the corner sections of the mandrel of the electroforming system of FIG. 7;

FIG. 12 illustrates a sectional view (along section VI-VI in FIG. 11) of one of the corner sections of the mandrel of the electroforming system of FIG. 7;

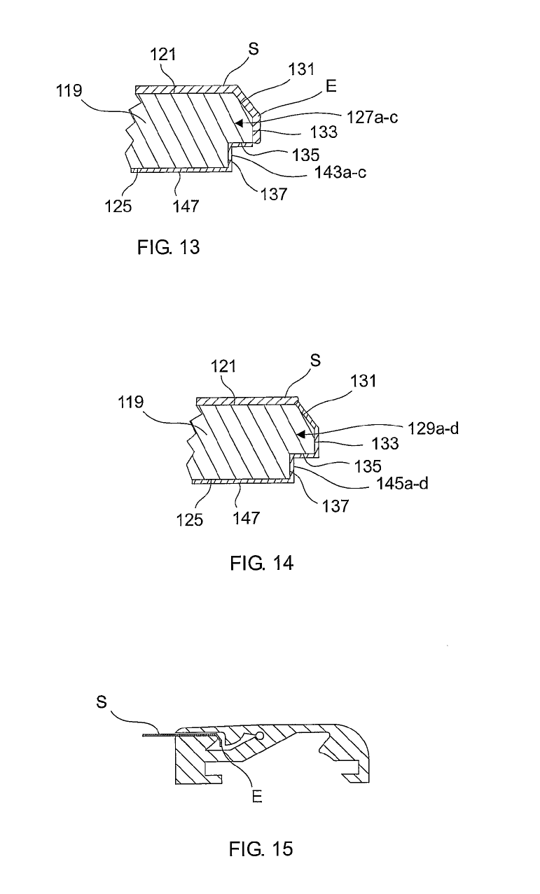

FIG. 13 illustrates a sectional view (along section V-V in FIG. 8) of one of the edge sections of the mandrel of the electroforming system of FIG. 7, where including a printing screen in accordance with a first embodiment of the present invention electroformed thereon;

FIG. 14 illustrates a sectional view (along section VI-VI in FIG. 11) of one of the corner sections of the mandrel of the electroforming system of FIG. 7, where including a printing screen in accordance with a first embodiment of the present invention electroformed thereon;

FIG. 15 illustrates an attachment element formed at one edge of the printing screen in accordance with the first embodiment of the present invention where located in a representative frame member of a mounting frame;

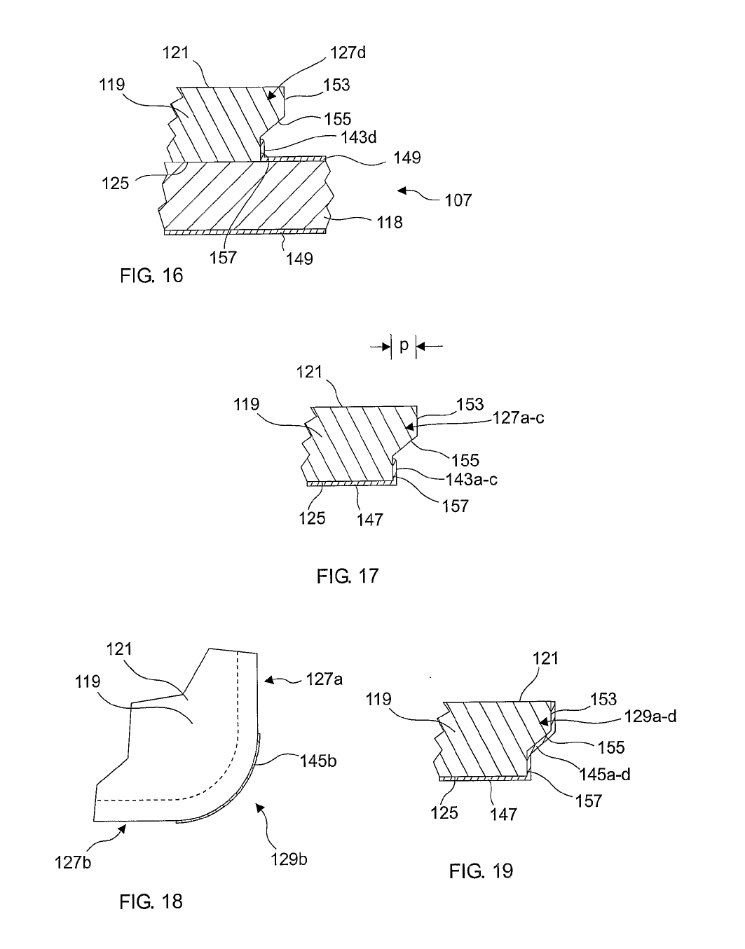

FIG. 16 illustrates a sectional view (along section IV-IV in FIG. 8) of one edge section of a mandrel as one modification of the electroforming system of FIG. 7;

FIG. 17 illustrates a sectional view (along section V-V in FIG. 8) of one of the other edge sections of the mandrel of the one modification of the electroforming system of FIG. 7;

FIG. 18 illustrates a plan view (region A in FIG. 8) of one of the corner sections of the mandrel of the one modification of the electroforming system of FIG. 7;

FIG. 19 illustrates a sectional view (along section VI-VI in FIG. 11) of one of the corner sections of the mandrel of the one modification of the electroforming system of FIG. 7;

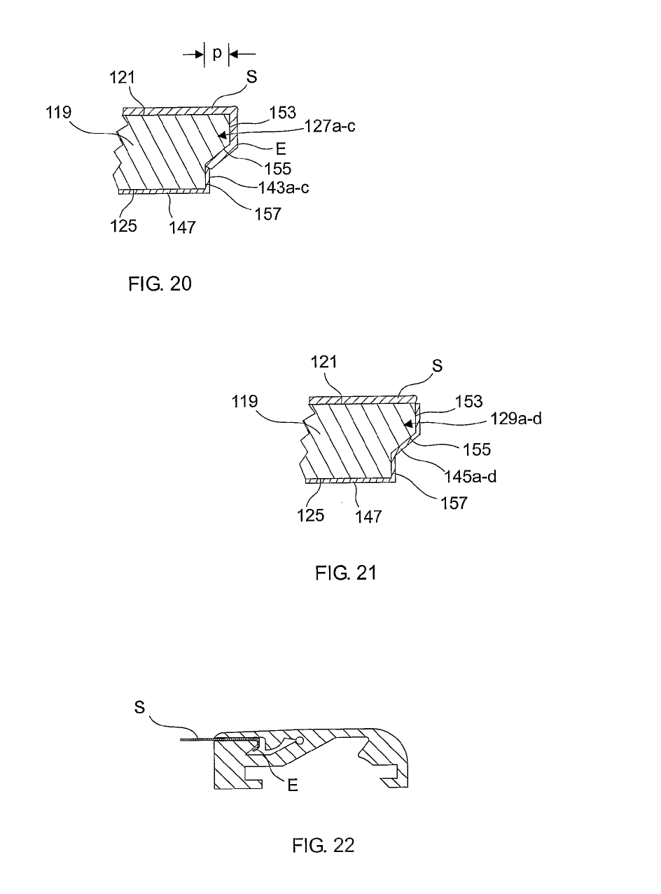

FIG. 20 illustrates a sectional view (along section V-V in FIG. 8) of one of the edge sections of the mandrel of the one modification of the electroforming system of FIG. 7, where including a printing screen in accordance with a second embodiment of the present invention electroformed thereon;

FIG. 21 illustrates a sectional view (along section VI-VI in FIG. 11) of one of the corner sections of the mandrel of the one modification of the electroforming system of FIG. 7, where including a printing screen in accordance with a second embodiment of the present invention electroformed thereon;

FIG. 22 illustrates an attachment element formed at one edge of the printing screen in accordance with the second embodiment of the present invention where located in a representative frame member of a mounting frame;

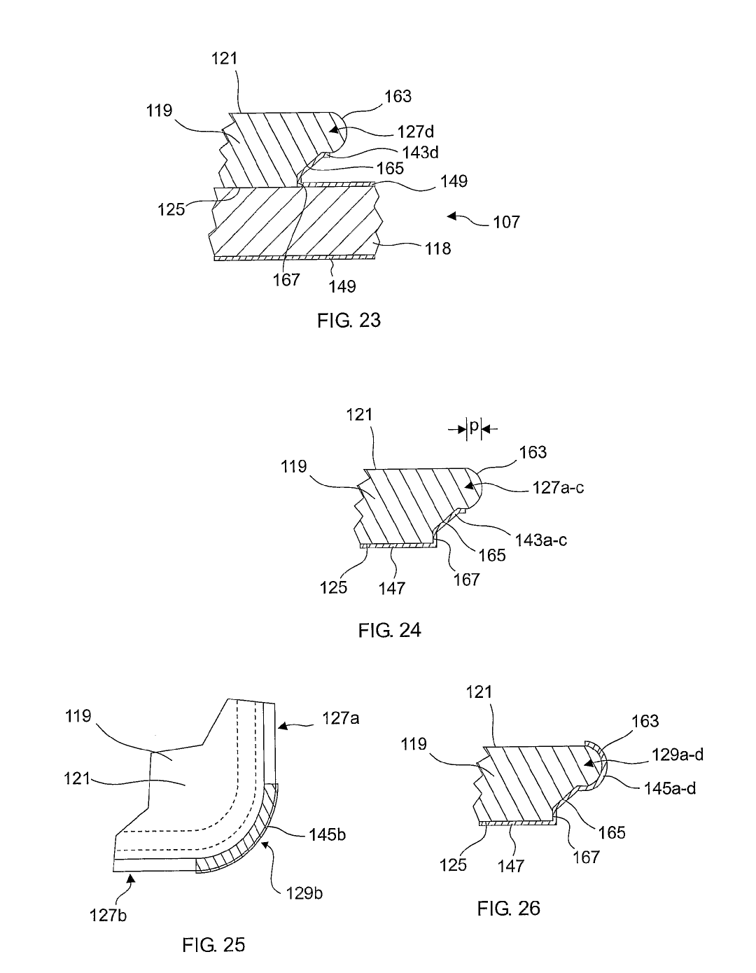

FIG. 23 illustrates a sectional view (along section IV-IV in FIG. 8) of one edge section of a mandrel as another modification of the electroforming system of FIG. 7;

FIG. 24 illustrates a sectional view (along section V-V in FIG. 8) of one of the other edge sections of the mandrel of the other modification of the electroforming system of FIG. 7;

FIG. 25 illustrates a plan view (region A in FIG. 8) of one of the corner sections of the mandrel of the other modification of the electroforming system of FIG. 7;

FIG. 26 illustrates a sectional view (along section VI-VI in FIG. 11) of one of the corner sections of the mandrel of the other modification of the electroforming system of FIG. 7;

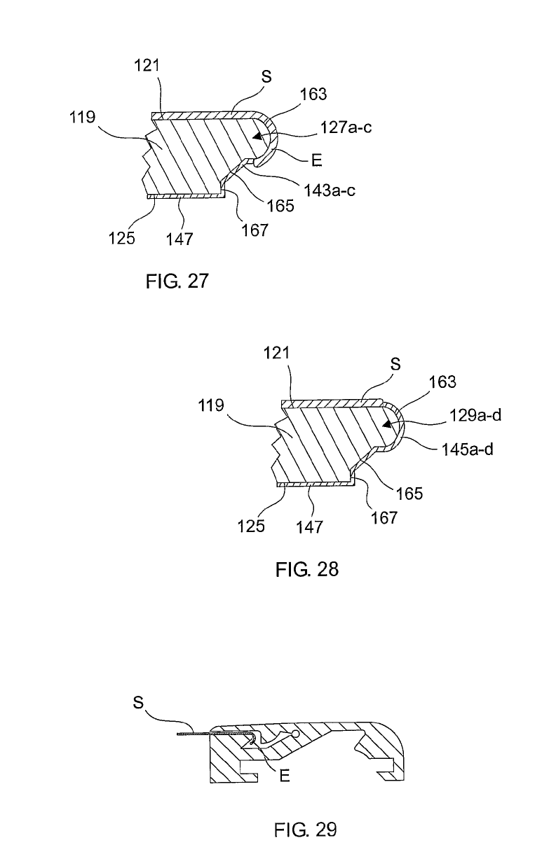

FIG. 27 illustrates a sectional view (along section V-V in FIG. 8) of one of the edge sections of the mandrel of the other modification of the electroforming system of FIG. 7, where including a printing screen in accordance with a third embodiment of the present invention electroformed thereon;

FIG. 28 illustrates a sectional view (along section VI-VI in FIG. 11) of one of the corner sections of the mandrel of the other modification of the electroforming system of FIG. 7, where including a printing screen in accordance with a third embodiment of the present invention electroformed thereon;

FIG. 29 illustrates an attachment element formed at one edge of the printing screen in accordance with the third embodiment of the present invention where located in a representative frame member of a mounting frame;

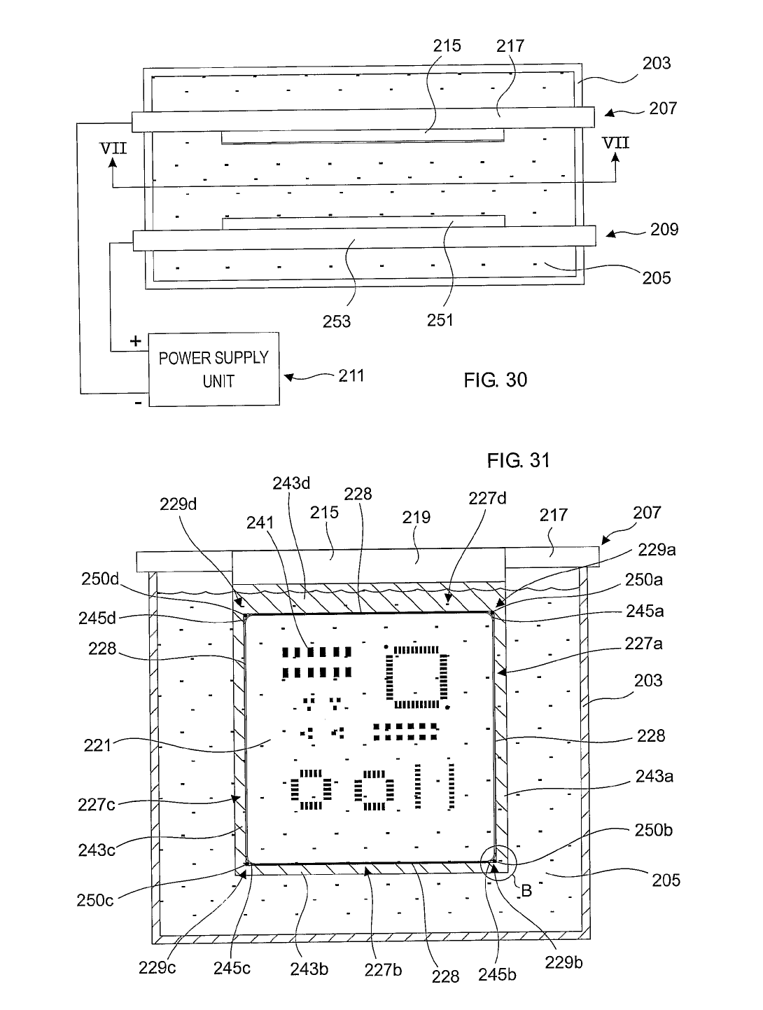

FIG. 30 illustrates an electroforming system in accordance with a second embodiment of the present invention;

FIG. 31 illustrates a vertical sectional view (along section VII-VII in FIG. 30) through the electroforming bath of the electroforming system of FIG. 30;

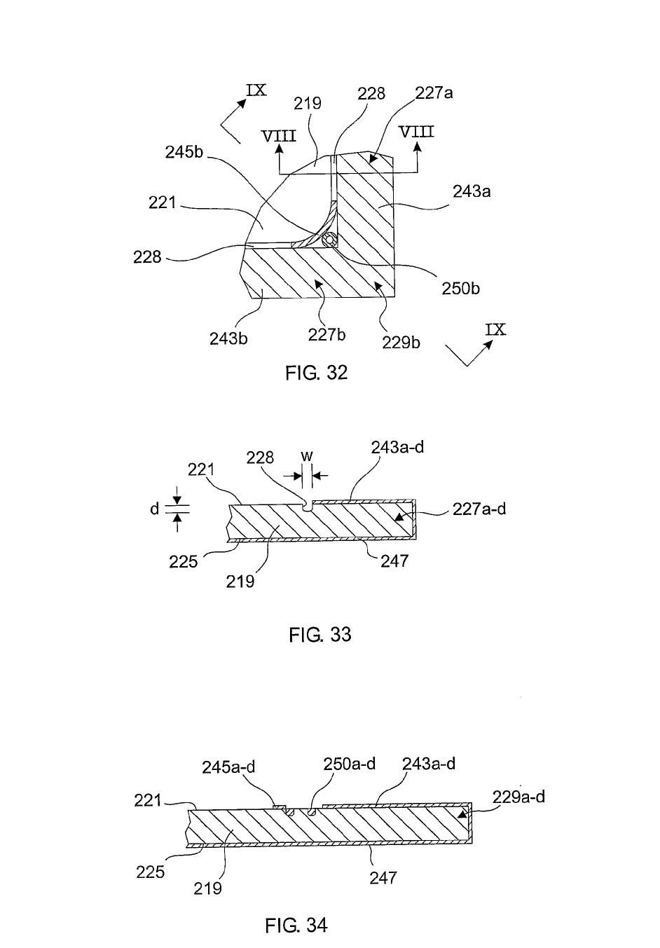

FIG. 32 illustrates a plan view (region B in FIG. 31) of one of the corner sections of the mandrel of the electroforming system of FIG. 30;

FIG. 33 illustrates a sectional view (along section VIII-VIII in FIG. 32) of one of the edge sections of the mandrel of the electroforming system of FIG. 30;

FIG. 34 illustrates a sectional view (along section IX-IX in FIG. 32) of one of the corner sections of the mandrel of the electroforming system of FIG. 30;

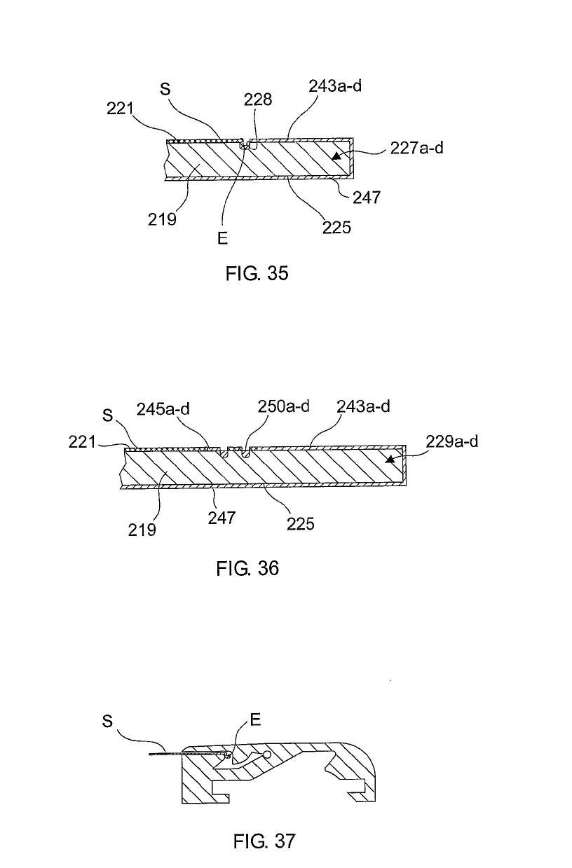

FIG. 35 illustrates a sectional view (along section VIII-VIII in FIG. 32) of one of the edge sections of the mandrel of the electroforming system of FIG. 30, where including a printing screen in accordance with a fourth embodiment of the present invention electroformed thereon;

FIG. 36 illustrates a sectional view (along section IX-IX in FIG. 32) of one of the corner sections of the mandrel of the electroforming system of FIG. 30, where including a printing screen in accordance with a fourth embodiment of the present invention electroformed thereon; and

FIG. 37 illustrates an attachment element formed at one edge of the printing screen in accordance with the fourth embodiment of the present invention where located in a representative frame member of a mounting frame.

FIGS. 7 to 14 illustrate an electroforming system in accordance with a first embodiment of the present invention.

The electroforming system comprises a bath 103 which contains an electrolyte solution 105, a mandrel unit 107 which is disposed in the bath 103 and onto which a printing screen S is to be electroformed, an anode unit 109 which is disposed in the bath 103 such as to provide a source of ions of the metal to be deposited, and a power supply unit 111 which is electrically connected to the mandrel unit 107 and the anode unit 109 and operable to drive an electric current through the electrolyte solution 105, with the negative supply of the power supply unit 111 being connected to the mandrel unit 107 and the positive supply of the power supply unit 111 being connected to the anode unit 109.

The electrolyte solution 105 is typically an aqueous solution which contains a dissolved salt of the metal to be deposited, commonly nickel, and levellers which provide for control of the hardness of the deposited metal.

The mandrel unit 107 comprises a mandrel 115 onto which the printing screen S is to be electroformed, a supporting member 117, in this embodiment a supporting bar, for supporting the mandrel 115 in the bath 103 and providing an electrical connection therewith, and an interconnecting member 118 for mechanically and electrically interconnecting the mandrel 115 to the supporting member 117.

The mandrel 115 comprises a flat metal mandrel plate 119 which includes first and second oppositely-directed flat, major surfaces 121, 125, where one major surface 121 is a deposition surface onto which metal is deposited to form the printing screen S, as will be described in more detail hereinbelow.

In this embodiment the mandrel plate 119 comprises a substantially rectangular metal plate which includes first to fourth substantially straight outer edge sections 127a-d and first to fourth corner sections 129a-d, here of arcuate shape, which connect respective ones of the edge sections 127a-d. In this embodiment the edge and corner sections 127a-d, 129a-d define a continuous peripheral section.

Referring particularly to FIGS. 9 and 10, each of the edge sections 127a-d comprises a first, inclined surface 131 which is inclined outwardly and rearwardly from the respective edge of the deposition surface 121 such as to extend at an obtuse angle therefrom, a second, outer surface 133 which extends from the outer end of the inclined surface 131 in a direction substantially perpendicular to the deposition surface 121, a third, return surface 135 which extends inwardly from the lower end of the outer surface 133 in a direction substantially parallel to the deposition surface 121, and a fourth, recessed surface 137 which extends from the inner end of the return surface 135 to the other major surface 125 in a direction substantially perpendicular to the deposition surface 121. As will be described in more detail hereinbelow, the inclined and outer surfaces 131, 133 remain exposed to receive metal deposit, resulting in the formation of rearwardly and outwardly depending attachment elements E of the electroformed printing screen S.

The mandrel 115 further comprises a plurality of non-conductive aperture-defining elements 141, in this embodiment formed of resist, disposed on the deposition surface 121 which shield regions of the deposition surface 121 onto which metal is not to be deposited, with these elements 141 corresponding to the apertures to be formed in the printing screen S, in this embodiment printing apertures through which a pattern of a printing medium is to be printed.

Referring particularly to FIGS. 9 and 10, the mandrel 115 further comprises first to fourth non-conductive edge elements 143a-d, in this embodiment formed of resist, which each shield the return and recessed surfaces 135, 137 of a respective one of the edge sections 127a-d, leaving the inclined and outer surfaces 131, 133 of the edge sections 127a-d exposed to receive metal deposit.

Referring particularly to FIGS. 11 and 12, the mandrel 115 further comprises non-conductive corner elements 145a-d, in this embodiment formed of resist, which each shield a respective one of the corner sections 129a-d, such that deposit is received only on the substantially straight edge sections 127a-d.

Referring particularly to FIGS. 10 and 12, the mandrel 115 further comprises a non-conductive surface-covering element 147, in this embodiment formed of resist, which shields the other major surface 125 of the mandrel plate 119, such as to prevent the deposition of metal thereon.

Referring particularly to FIG. 9, the mandrel unit 107 further comprises a non-conductive surface-covering element 149, in this embodiment formed of resist, which shields the interconnecting member 118, such as to prevent the deposition of metal thereon

The anode unit 109 comprises an anode plate 151, in this embodiment of the same rectangular shape as the mandrel 115, which is formed of the metal to be deposited as the printing screen S, and a supporting member 153, in this embodiment a supporting bar, for supporting the anode plate 151 in the bath 103 and providing an electrical connection therewith.

In a preferred embodiment the deposition surface 121 of the mandrel plate 119 and the anode plate 151 are disposed in opposed, parallel relation at a predetermined spacing.

In operation, the power supply unit 111 is actuated to drive an electric current through the electrolyte solution 105 between the mandrel unit 107 and the anode unit 109. This current causes metal ions to migrate from the anode plate 151 to the exposed surfaces of the mandrel plate 119, at which exposed surfaces, that is, the exposed regions of the deposition surface 121 and the exposed inclined and outer surfaces 131, 133 of the edge sections 127a-d, the metal ions deposit as the metal, building up the printing screen S by continued deposition on the mandrel plate 119.

This process is allowed to continue until a deposit of the required thickness, which constitutes the printing screen S, has been built up on the mandrel 115, as illustrated in FIGS. 13 and 14, at which point the power supply unit 111 is de-actuated and the mandrel unit 107 removed from the bath 103. FIGS. 13 and 14 illustrate a printing screen S in accordance with a first embodiment of the present invention, which includes attachment elements E at the respective edges thereof.

The non-conductive elements 141, 143a-d, 145a-d, 147, 149 are then removed, in this embodiment by stripping the resist, leaving the printing screen S.

The printing screen S is then separated from the mandrel 115, and, following cleaning, is ready for use.

FIG. 15 illustrates the location of the attachment element E formed at one edge of the printing screen S in a representative frame member of a mounting frame.

FIGS. 16 to 21 illustrate fragmentary views of a mandrel unit 107 as one modification of the first-described embodiment.

The mandrel unit 107 of this embodiment is very similar to that of the above-described first embodiment, and differs only in the configuration of the edge and corner sections 127a-d, 129a-d of the mandrel plate 119.

In this embodiment each of the edge sections 127a-d comprises a first, outer surface 153 which extends from the respective edge of the deposition surface 121 in a direction substantially perpendicular thereto, a second, return surface 155 which extends inwardly and rearwardly from the lower end of the outer surface 153, and a third, recessed surface 157 which extends from the inner end of the return surface 155 to the other major surface 125 in a direction substantially perpendicular to the deposition surface 121. As will be described in more detail hereinbelow, the outer and return surfaces 153, 155 remain exposed to receive metal deposit, resulting in rearwardly and inwardly extending attachment elements E of the electroformed printing screen S.

In this embodiment the first to fourth non-conductive edge elements 143a-d each shield the recessed surface 157 of a respective one of the edge sections 127a-d, leaving the outer and return surfaces 153, 155 of the edge sections 127a-d exposed to receive metal deposit.

In this embodiment the non-conductive corner elements 145a-d each shield a respective one of the corner sections 129a-d, such that deposit is received only on the substantially straight edge sections 127a-d.

In this embodiment the return surfaces 155, and thus the attachment elements E of the printing screen S, have a lateral projection p in a plane parallel to the deposition surface 121 of about 0.5 mm. As a consequence of the relatively small extent of the lateral projection p and the rearward taper of the return surface 155, and thus the attachment elements E of the printing screen S, the resilience, albeit limited, of the printing screen S allows the printing screen S to be released from the mandrel 115.

In operation, the power supply unit 111 is actuated to drive an electric current through the electrolyte solution 105 between the mandrel unit 107 and the anode unit 109. This current causes metal ions to migrate from the anode plate 151 to the exposed surfaces of the mandrel plate 119, at which exposed surfaces, that is, the exposed regions of the deposition surface 121 and the outer and return surfaces 153, 155 of the edge sections 127a-d, the metal ions deposit as the metal, building up the printing screen S by continued deposition on the mandrel plate 119.

This process is allowed to continue until a deposit of the required thickness, which constitutes the printing screen S, has been built up on the mandrel 115, as illustrated in FIGS. 20 and 21, at which point the power supply unit 111 is de-actuated and the mandrel unit 107 removed from the bath 103. FIGS. 20 and 21 illustrate a printing screen S in accordance with a second embodiment of the present invention, which includes attachment elements E at the respective edges thereof.

The non-conductive elements 141, 143a-d, 145a-d, 147 are then removed, in this embodiment by stripping the resist, leaving the printing screen S.

The printing screen S is then separated from the mandrel 115, and, following cleaning, is ready for use.

FIG. 22 illustrates the location of the attachment element E formed at one edge of the printing screen S in a representative frame member of a mounting frame.

FIGS. 23 to 28 illustrate fragmentary views of a mandrel unit 107 as another modification of the first-described embodiment.

The mandrel unit 107 of this embodiment is very similar to that of the above-described first embodiment, and differs only in the configuration of the edge and corner sections 127a-d, 129a-d of the mandrel plate 119.

In this embodiment each of the edge sections 127a-d comprises a first, hook surface 163, here of arcuate shape, which extends outwardly and rearwardly from the respective edge of the deposition surface 121 and returns inwardly and rearwardly to a location spaced rearwardly from and laterally inwardly of the respective edge of the deposition surface 121, a second, inclined surface 165 which extends inwardly and rearwardly from the rear, distal end of the hook surface 163, and a third, recessed surface 167 which extends from the inner end of the inclined surface 165 to the other major surface 125 in a direction substantially perpendicular to the deposition surface 121. As will be described in more detail hereinbelow, major regions of the hook surfaces 163 remain exposed to receive metal deposit, resulting in inwardly-directed, hook-shaped attachment elements E of the formed printing screen S.

In this embodiment the first to fourth non-conductive edge elements 143a-d each shield a region of the distal end of the hook surface 163 and the inclined and recessed surfaces 165, 167 of a respective one of the edge sections 127a-d, leaving major regions of the hook surfaces 163 of the edge sections 127a-d exposed to receive metal deposit.

In this embodiment the non-conductive corner elements 145a-d each shield a respective one of the corner sections 129a-d, such that deposit is received only on the substantially straight edge sections 127a-d.

In this embodiment the exposed regions of the hook surfaces 163, and thus the attachment elements E of the printing screen S, have a lateral projection p in a plane parallel to the deposition surface 121 of about 0.5 mm. As a consequence of the relatively small extent of the lateral projection p and the rearward and inward arcuate extension of the hook surface 163, and thus the attachment elements E of the printing screen S, the resilience, albeit limited, of the printing screen S allows the printing screen S to be released from the mandrel 115.

In operation, the power supply unit 111 is actuated to drive an electric current through the electrolyte solution 105 between the mandrel unit 107 and the anode unit 109. This current causes metal ions to migrate from the anode plate 151 to the exposed surfaces of the mandrel plate 119, at which exposed surfaces, that is, the exposed regions of the deposition surface 121 and the exposed regions of the hook surface 163 of the edge sections 127a-d, the metal ions deposit as the metal, building up the printing screen S by continued deposition on the mandrel plate 119.

This process is allowed to continue until a deposit of the required thickness, which constitutes the printing screen S, has been built up on the mandrel 115, as illustrated in FIGS. 27 and 28, at which point the power supply unit 111 is de-actuated and the mandrel unit 107 removed from the bath 103. FIGS. 27 and 28 illustrate a printing screen S in accordance with a third embodiment of the present invention, which includes attachment elements E at the respective edges thereof.

The non-conductive elements 141, 143a-d, 145a-d, 147 are then removed, in this embodiment by stripping the resist, leaving the printing screen S.

The printing screen S is then separated from the mandrel 115, and, following cleaning, is ready for use.

FIG. 29 illustrates the location of the attachment element E formed at one edge of the printing screen S in a representative frame member of a mounting frame.

FIGS. 30 to 36 illustrate an electroforming system in accordance with a second embodiment of the present invention.

The electroforming system comprises a bath 203 which contains an electrolyte solution 205, a mandrel unit 207 which is disposed in the bath 203 and onto which a printing screen S is to be electroformed, an anode unit 209 which is disposed in the bath 203 such as to provide a source of ions of the metal to be deposited, and a power supply unit 211 which is electrically connected to the mandrel unit 207 and the anode unit 209 and operable to drive an electric current through the electrolyte solution 205, with the negative supply of the power supply unit 211 being connected to the mandrel unit 207 and the positive supply of the power supply unit 211 being connected to the anode unit 209.

The electrolyte solution 205 is typically an aqueous solution which contains a dissolved salt of the metal to be deposited, commonly nickel, and levellers which provide for control of the hardness of the deposited metal.

The mandrel unit 207 comprises a mandrel 215 onto which the printing screen S is to be formed, and a supporting member 217, in this embodiment a supporting bar, for supporting the mandrel 215 in the bath 203 and providing an electrical connection therewith.

The mandrel 215 comprises a mandrel plate 219 which includes first and second oppositely-directed flat, major surfaces 221, 225, where one major surface 221 is a deposition surface onto which metal is deposited to form the printing screen S, as will be described in more detail hereinbelow.

In this embodiment the mandrel plate 219 comprises a flat metal plate which includes first to fourth substantially straight edge sections 227a-d, which each include an elongate channel 228 and together define the edges of a rectangle, and, as will become more apparent hereinbelow, the lateral extent of the printing screen S to be electroformed, and first to fourth corner sections 229a-d which connect respective ones of the edge sections 227a-d.

Referring particularly to FIGS. 32 and 33, in this embodiment each of the channels 228 has a U-shaped section which has a width w of about 0.6 mm and a depth d of about 0.5 mm, such that the channels 228 are sufficiently filled by the deposited metal to form attachment elements E. In another embodiment each of the channels 228 could have a width w of about 0.5 mm. In this embodiment the width w of the channels 228 is such that, when depositing a printing screen which has a thickness of about 0.25 mm, the channels 228 are substantially filled to form attachment elements E in the manner of beads, as will be described in more detail hereinbelow. In other embodiments, where depositing thinner printing screens, particularly at a thickness of about 0.05 mm, the attachment elements E are formed as open sections having a substantially U-shaped section. In this embodiment the channels 228 are cut into the mandrel plate 219, typically by machining or chemical etching.

The mandrel 215 further comprises a plurality of non-conductive aperture-defining elements 241 disposed on the deposition surface 221 which shield regions of the deposition surface 221 onto which metal is not to be deposited, with these elements 241 corresponding to the apertures to be formed in the printing screen S, in this embodiment printing apertures through which a pattern of a printing medium is to be printed.

Referring particularly to FIGS. 32 and 33, the mandrel 215 further comprises first to fourth non-conductive edge elements 243a-d which each shield a region of the respective edge section 227a-d outside of the rectangle defined by the channels 228 at the edge sections 227a-d, leaving the channels 228 at the edge sections 227a-d exposed to receive metal deposit.

Referring particularly to FIGS. 32 and 34, the mandrel 215 further comprises first to fourth non-conductive corner elements 245a-d, in this embodiment of arcuate shape, which connect the distal ends of respective ones of the channels 228 at the edge sections 227a-d. In this embodiment the corner elements 245a-d are disposed on the deposition surface 221. As will be described in more detail hereinbelow, the corner elements 245a-d act to prevent the main body of the formed printing screen S extending beyond the distal ends of the channels 228 at the edge sections 227a-d.

The mandrel 215 further comprises a non-conductive surface-covering element 247 which shields the other major surface 225 and the outer edges of the mandrel plate 219, such as to prevent the deposition of metal thereon.

In this embodiment the aperture-defining elements 241 and the corner elements 245a-d are formed of resist, and the edge elements 243a-d and the surface covering element 247 are provided by a permanent coating, here of Teflon (RTM).

The mandrel 215 further comprises first to fourth non-conductive reference elements 250a-d disposed at respective ones of the corner sections 229a-d, which act to provide a means of reference when positioning a photo-mask in patterning the aperture-defining elements 241 relative to the channels 228 at the edge sections 227a-d. In this embodiment the reference elements 250a-d are annular fiducials which are defined by non-conductive annular elements, here formed of an epoxy resin, disposed in an annular channel cut into the mandrel plate 219.

The anode unit 209 comprises an anode plate 251, in this embodiment of the same rectangular shape as the mandrel 215, which is formed of the metal to be deposited as the printing screen S, and a supporting member 253, in this embodiment a supporting bar, for supporting the anode plate 251 in the bath 203 and providing an electrical connection therewith.

In a preferred embodiment the deposition surface 221 of the mandrel plate 219 and the anode plate 251 are disposed in opposed, parallel relation at a predetermined spacing.

In operation, the power supply unit 211 is actuated to drive an electric current through the electrolyte solution 205 between the mandrel unit 207 and the anode unit 209. This current causes metal ions to migrate from the anode plate 251 to the exposed surfaces of the mandrel plate 219, at which exposed surfaces, that is, the exposed regions of the deposition surface 221 and the channels 228 at the edge sections 227a-d, the metal ions deposit as the metal, building up the printing screen S by the continued deposition on the mandrel plate 219.

This process is allowed to continue until a deposit of the required thickness, which constitutes the printing screen S, has been built up on the mandrel plate 219, as illustrated in FIGS. 35 and 36, at which point the power supply unit 211 is de-actuated and the mandrel unit 207 removed from the bath 203. FIGS. 35 and 36 illustrate a printing screen S in accordance with a fourth embodiment of the present invention, which includes attachment elements E at the respective edges thereof.

The aperture-defining elements 241 and the corner elements 245a-d are then removed, in this embodiment by stripping the resist, leaving the printing screen S.

The printing screen S is then separated from the mandrel plate 219, and, following cleaning, is ready for use.

FIG. 37 illustrates the location of the attachment element E formed at one edge of the printing screen S in a representative frame member of a mounting frame.

Finally, it will be understood that the present invention has been described in its preferred embodiments and can be modified in many different ways without departing from the scope of the invention as defined by the appended claims.

1. A mandrel for electroforming printing screens, the mandrel comprising:
a mandrel plate onto which metal is to be deposited to form a printing screen, the mandrel plate including a main deposition surface onto which metal is to be deposited to define a main body of the printing screen, at least one pair of edge sections at opposed edges of the main deposition surface which include edge deposition surfaces which extend out of a plane defined by the main deposition surface onto which metal is to be deposited to define attachment elements of the printing screen, and corner sections at respective corners of the deposition surface;
non-conductive elements, as edge elements, which are disposed at the edge sections such as to define an extent of the edge sections; and
non-conductive elements, as corner elements, which are disposed at the corner sections such as to shield the same and define an extent of the main deposition surface at the corner sections.

2. The mandrel of claim 1, further comprising:
non-conductive elements disposed on the main deposition surface which shield regions of the main deposition surface, corresponding to printing apertures, onto which metal is not to be deposited.

3. The mandrel of claim 1, wherein each edge deposition surface includes a surface section which extends laterally relative to the main deposition surface.

4. The mandrel of claim 3, wherein the surface section extends laterally outwardly relative to the respective edge of the main deposition surface, which provides for deposition of an outwardly-projecting part.

5. The mandrel of claim 3, wherein the surface section extends laterally inwardly relative to the respective edge of the main deposition surface, which provides for deposition of an inwardly-projecting part.

6. The mandrel of claim 5, wherein the surface section returns inwardly a distance of about 0.5 mm.

7. The mandrel of claim 3, wherein the surface section comprises a substantially straight section.

8. The mandrel of claim 3, wherein the surface section comprises an arcuate section.

9. The mandrel of claim 3, wherein the surface section extends rearwardly of the main deposition surface.

10. The mandrel of claim 1, wherein each edge deposition surface includes first and second surface sections, wherein the first surface section extends substantially orthogonally relative to the main deposition surface and the second surface section extends laterally relative to the main deposition surface.

11. The mandrel of claim 10, wherein the second surface section extends laterally outwardly relative to the respective edge of the main deposition surface, which provides for deposition of an outwardly-projecting part.

12. The mandrel of claim 10, wherein the second surface section extends laterally inwardly relative to the respective edge of the main deposition surface, which provides for deposition of an inwardly-projecting part.

13. The mandrel of claim 12, wherein the second surface section returns inwardly a distance of about 0.5 mm.

14. The mandrel of claim 10, wherein the second surface section comprises a substantially straight section.

15. The mandrel of claim 10, wherein the second surface section comprises an arcuate section.

16. The mandrel of claim 10, wherein the first surface section extends from the respective edge of the main deposition surface and the second surface section extends from the first surface section.

17. The mandrel of claim 10, wherein the second surface section extends from the respective edge of the main deposition surface and the first surface section extends from the second surface section.

18. The mandrel of claim 10, wherein the first and second surface sections extend rearwardly of the main deposition surface.

19. The mandrel of claim 1, wherein each edge deposition surface includes first and second surface sections, wherein the first surface section extends laterally in one sense relative to the main deposition surface and the second surface section extends laterally in the other sense relative to the main deposition surface.

20. The mandrel of claim 19, wherein the first surface section extends laterally outwardly relative to the respective edge of the main deposition surface, which provides for deposition of an outwardly-projecting part, and the second surface section extends laterally inwardly relative to the respective edge of the main deposition surface, which provides for deposition of an inwardly-projecting part.

21. The mandrel of claim 20, wherein the second surface section returns inwardly a distance of about 0.5 mm.

22. The mandrel of claim 19, wherein one or both of the first and second surface sections comprise a substantially straight section.

23. The mandrel of claim 19, wherein one or both of the first and second surface sections comprise an arcuate section.

24. The mandrel of claim 19, wherein the first and second surface sections extend rearwardly of the main deposition surface.

25. The mandrel of claim 1, wherein the edge sections each comprise a channel at the respective edge of the main deposition surface in which metal is deposited to form an attachment element.

26. The mandrel of claim 25, wherein the channel has a width of about 0.5 mm to about 0.6 mm.

27. The mandrel of claim 25, wherein the channel has a width of about 0.5 mm or about 0.6 mm.

28. The mandrel of claim 25, wherein the channel has a substantially U-shaped section.

29. The mandrel of claim 1, wherein the mandrel plate includes first and second pairs of edge sections at opposed edges of the main deposition surface.

30. The mandrel of claim 29, wherein the edge sections and the corner sections define a continuous peripheral section.

31. An electroforming system including the mandrel of claim 1.

32. A method of electroforming printing screens, comprising the steps of:
providing the mandrel of claim 1 in an electroforming bath; and
electrodepositing metal on the mandrel plate such as to form a printing screen.

33. An electroformed printing screen, comprising a main body including a pattern of printing apertures through which a printing medium is in use printed, and at least one pair of attachment elements at opposed edges of the main body, wherein the attachment elements each extend out of a plane defined by the main body and along only part of a length of the respective edge of the main body.

34. The printing screen of claim 33, wherein each corner of the main body is recessed, such that the attachment elements are separate from one another.

35. The printing screen of claim 33, wherein each attachment element includes a projecting part which extends laterally relative to the respective edge of the main body.

36. The printing screen of claim 35, wherein the projecting part extends laterally outwardly relative to the respective edge of the main body.

37. The printing screen of claim 35, wherein the projecting part extends laterally inwardly relative to the respective edge of the main body.

38. The printing screen of claim 37, wherein the projecting part returns inwardly a distance of about 0.5 mm.

39. The printing screen of claim 35, wherein the projecting part comprises a substantially straight section.

40. The printing screen of claim 35, wherein the projecting part comprises an arcuate section.

41. The printing screen of claim 35, wherein the projecting part extends rearwardly of the main body.

42. The printing screen of claim 33, wherein each attachment element includes first and second projecting parts, wherein the first projecting part extends substantially orthogonally relative to the main body and the second projecting part extends laterally relative to the main body.

43. The printing screen of claim 42, wherein the second projecting part extends laterally outwardly relative to the respective edge of the main body.

44. The printing screen of claim 42, wherein the second projecting part extends laterally inwardly relative to the respective edge of the main body.

45. The printing screen of claim 44, wherein the second projecting part returns inwardly a distance of about 0.5 mm.

46. The printing screen of claim 42, wherein the second projecting part comprises a substantially straight section.

47. The printing screen of claim 42, wherein the second projecting part comprises an arcuate section.

48. The printing screen of claim 42, wherein the first projecting part extends from the respective edge of the main body and the second projecting part extends from the first projecting part.

49. The printing screen of claim 42, wherein the second projecting part extends from the respective edge of the main body and the first projecting part extends from the second projecting part.

50. The printing screen of claim 42, wherein the first and second projecting parts extend rearwardly of the main body.

51. The printing screen of claim 33, wherein each attachment element includes first and second projecting parts, wherein the first projecting part extends laterally in one sense relative to the main body and the second projecting part extends laterally in the other sense relative to the main body.

52. The printing screen of claim 51, wherein the first projecting part extends laterally outwardly relative to the respective edge of the main body, and the second projecting part extends laterally inwardly relative to the respective edge of the main body.

53. The printing screen of claim 52, wherein the second projecting part returns inwardly a distance of about 0.5 mm.

54. The printing screen of claim 51, wherein one or both of the first and second projecting parts comprise a substantially straight section.

55. The printing screen of claim 51, wherein one or both of the first and second projecting parts comprise an arcuate section.

56. The printing screen of claim 51, wherein the first and second projecting parts extend rearwardly of the main body.

57. The printing screen of claim 33, wherein the attachment elements each comprise an open section.

58. The printing screen of claim 57, wherein the open section has a width of about 0.5 mm to about 0.6 mm.

59. The printing screen of claim 57, wherein the open section has a width of about 0.5 mm or about 0.6 mm.

60. The printing screen of claim 57, wherein the open section comprises a substantially U-shaped section.

61. The printing screen of claim 33, wherein the attachment elements each comprise a bead.

62. The printing screen of claim 61, wherein the bead has a width of about 0.5 mm to about 0.6 mm.

63. The printing screen of claim 61, wherein the bead has a width of about 0.5 mm or about 0.6 mm.

64. The printing screen of claim 61, wherein the bead comprises a hollow body.

65. The printing screen of claim 33, comprising first and second pairs of opposed attachment elements.

66. An electroformed printing screen, comprising a main body including a pattern of printing apertures through which a printing medium is in use printed, and at least one pair of attachment elements at opposed edges of the main body, wherein the attachment elements each include a projecting part which extends laterally outwardly relative to the respective edge of the main body and out of a plane defined by the main body and along only part of a length of the respective edge of the main body.

67. An electroformed printing screen, comprising a main body including a pattern of printing apertures through which a printing medium is in use printed, and at least one pair of attachment elements at opposed edges of the main body, wherein the attachment elements each comprise a bead which extends out of a plane defined by the main body and along only part of a length of the respective edge of the main body.
